(19) United States
(12) Patent Application Publication
(10) Pub. No.: US 2011/0310544 A1
(43) Pub. Date: Dec. 22, 2011

(54) Coupling Systems for Removably Coupling a Support Beam to an Electronic Device and Methods of Making and Using the Same

(76) Inventor: Arthur Larsen, Lancaster, PA (US)

(21) Appl. No.: 13/165,938

(22) Filed: Jun. 22, 2011

Related U.S. Application Data
(60) Provisional application No. 61/357,532, filed on Jun. 23, 2010.

(51) Int. Cl. H05K 7/00; F16B 47/00

(52) U.S. Cl. 361/679.01; 248/309.1

(57) ABSTRACT

Coupling systems for removably coupling a support beam to an electronic device (e.g., cellular phone) are disclosed. Methods of making and using coupling systems for removably coupling a support beam to an electronic device are also disclosed.

### CROSS-REFERENCE TO RELATED APPLICATIONS

This patent application claims the benefit of priority to U.S. Provisional Patent Application Ser. No. 61/357,532, filed on Jun. 23, 2010 and entitled “MECHANISM FOR REMOVABLY COUPLING A SUPPORT BEAM TO AN OBJECT,” the subject matter of which is hereby incorporated by reference in its entirety.

### FIELD OF THE INVENTION

The present invention relates to electronic device coupling systems for removably coupling a support beam to an electronic device (e.g., cellular phone), methods of making electronic device coupling systems for removably coupling a support beam to an electronic device, and methods of using electronic device coupling systems for removably coupling a support beam to an electronic device.

### BACKGROUND OF THE INVENTION

The use of hand-held electronic devices such as cellular phones, smart phones, computer pads, etc. continues to grow at an astonishing pace. To view the screen display of such devices, the screen display is typically viewed when held at an orthogonal angle to the viewer's line of sight. When a viewer wants to view the screen display for an extended period of time, the viewer typically has to hand hold the device so that the screen display is at an orthogonal angle to the viewer's line of sight. An alternative is to place the device on a flat surface; however, given that many electronic devices lack a built-in support system, viewing of the screen display positioned on a flat surface leads to an uncomfortable viewing experience due to the angle of view.

What is needed in the art is a simple electronic device coupling system that enables a screen display of an electronic device to be positioned at an orthogonal angle to the viewer's line of sight when placed on a flat surface.

### SUMMARY OF THE INVENTION

The present invention is directed to electronic device coupling systems removably coupling a support beam or member to an electronic device, such as a hand-held electronic device (e.g., a cellular phone). The disclosed electronic device coupling systems of the present invention enable a screen display of an electronic device to be positioned at an orthogonal angle to the viewer's line of sight when placed on a flat surface. The electronic device coupling systems of the present invention provide one or more of the following features: (i) a coupling member that forms a portion of an outer housing of an electronic device (e.g., a cellular phone); (ii) a coupling member that is attachable to a portion of an outer housing of an electronic device (e.g., a cellular phone); (iii) a coupling member that enables upright and/or horizontal support of an electronic device (e.g., a cellular phone) in an angular position relative to a flat surface on which the electronic device is placed; (iv) a coupling member in combination with an electronic device (e.g., a cellular phone), wherein the coupling member/electronic device combination is supportable by a support member removably attached to the combination; and (iv) a coupling member in combination with an electronic device (e.g., a cellular phone) and a support member (e.g., a card) having sufficient rigidity so as to support both the coupling member and electronic device in combination.

According to one exemplary embodiment of the present invention, the electronic device coupling system comprises an outer housing for an electronic device; and a coupling member having a front surface, a rear surface, and at least one groove extending along (i) the front surface, (ii) the rear surface or (iii) both of the front and rear surfaces, each of the at least one groove comprising a first groove side surface, a second groove side surface opposite the first groove side surface, and a groove end surface; wherein the coupling member either (i) forms at least a portion of the outer housing or (ii) is attachable to at least a portion of the outer housing

In further exemplary embodiments of the present invention, the electronic device coupling system is directed to an electronic device coupling system comprising a coupling member having a front surface, a rear surface, and at least one groove extending along (i) the front surface, (ii) the rear surface or (iii) both of the front and rear surfaces, each of the at least one groove comprising a first groove side surface, a second groove side surface opposite the first groove side surface, and a groove end surface; wherein the coupling member comprises two grooves with the two grooves being positioned at a substantially orthogonal angle to one another. In this embodiment, the two grooves may comprise (i) a first groove having a first groove angle relative to a rear surface of the coupling member, and (ii) a second groove having a second groove angle relative to the rear surface of the coupling member, wherein the first groove angle is the same as or different from the second groove angle.

The present invention is further directed to methods of making electronic device coupling systems and methods of using electronic device coupling systems to removably couple a support beam or member to an electronic device, such as a hand-held electronic device (e.g., a cellular phone).

The present invention is even further directed to electronic device coupling systems comprising one or more of the herein described coupling members in combination with (1) one or more electronic devices; (2) one or more support members; (3) one or more outer housing components (e.g., a housing backing, a housing component comprising a housing opening sized for placement of a screen display therein, a battery housing cover, a protective accessory casing, etc.); or (4) any combination of (1) to (3).

These and other features and advantages of the present invention will become apparent after a review of the following detailed description of the disclosed embodiments and the appended claims.

### BRIEF DESCRIPTION OF THE FIGURES

The present invention is further described with reference to the appended figures, wherein:

FIG. 1 depicts a view of exemplary components used to form an exemplary electronic device coupling system of the present invention;

FIG. 2a depicts a rear view of the exemplary coupling member in the exemplary electronic device coupling system shown in FIG. 1;

FIG. 2b-2c depict cross-sectional views of the exemplary coupling member shown in FIG. 2a along views B-B and C-C respectively;

FIG. 3 depicts a side view of the exemplary coupling member shown in FIG. 2a positioned in an upright position;

FIG. 4 depicts a side view of the exemplary coupling member shown in FIG. 2a positioned in a horizontal position;

FIG. 5 depicts a view of exemplary components used to form another exemplary electronic device coupling system of the present invention;

FIG. 6 depicts a frontal perspective view of an exemplary coupling member suitable for use in the exemplary electronic device coupling system shown in FIG. 5;

FIG. 7 depicts a side view of the exemplary coupling member shown in FIG. 6;

FIG. 8 depicts a view of the exemplary coupling member shown in FIG. 6 attached to a rear surface of an exemplary electronic device;

FIG. 9 depicts a side view of the exemplary coupling member/exemplary electronic device combination shown in FIG. 8 supported by an exemplary support member in an upright position;

FIG. 10 depicts a side view of the exemplary coupling member/exemplary electronic device combination shown in FIG. 8 supported by an exemplary support member in a horizontal position;

FIG. 11 depicts a rear view of the exemplary coupling member/exemplary electronic device/exemplary support member combination shown in FIG. 10;

FIG. 12 depicts frontal views of exemplary shapes for fifteen exemplary coupling members suitable for use in the exemplary electronic device coupling systems shown in FIGS. 1-2;

FIG. 13 depicts a frontal perspective view of another exemplary coupling member suitable for use in the exemplary electronic device coupling systems shown in FIGS. 1-2;

FIG. 14 depicts a rear perspective view of the exemplary coupling member shown in FIG. 13 attached to a rear surface of an exemplary electronic device and supported by an exemplary support member in an upright position;

FIG. 15 depicts various exemplary shapes for four exemplary coupling members suitable for use in the exemplary electronic device coupling systems shown in FIGS. 1-2;

FIGS. 16a-16c depict frontal and side views of another exemplary coupling member suitable for use in the exemplary electronic device coupling systems shown in FIGS. 1-2;

FIG. 17 depicts an exemplary coupling member suitable for use in the exemplary electronic device coupling systems shown in FIGS. 1-2, wherein grooves have one or more curved groove surfaces; and

FIGS. 18a-18b depict cross-sectional side views of an exemplary groove configuration of another exemplary coupling member suitable for use in the exemplary electronic device coupling systems shown in FIGS. 1-2, wherein opposing side surfaces of a groove move from a closed to an open configuration when a support member is inserted therebetween.

### DETAILED DESCRIPTION OF THE INVENTION

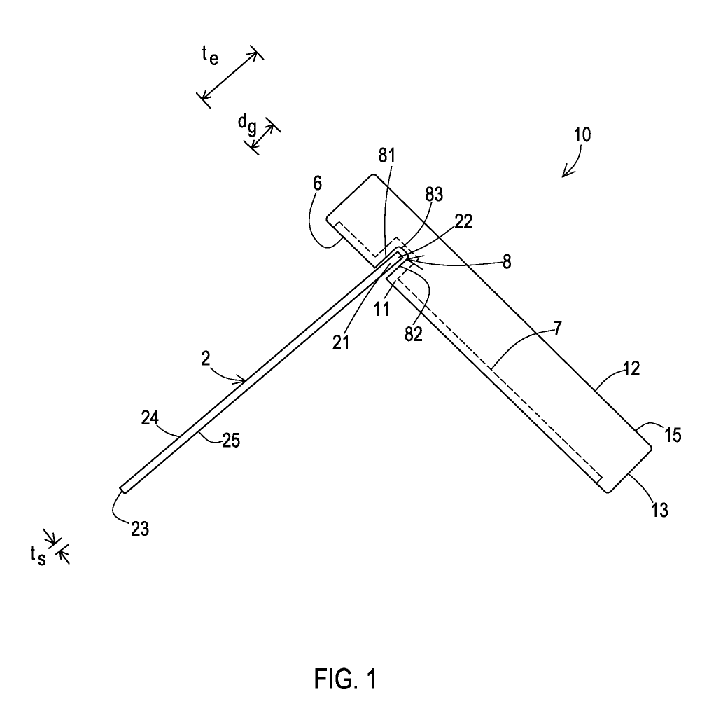

The present invention is directed to electronic device coupling systems, methods of making electronic device coupling systems, and methods of using electronic device coupling systems. FIG. 1 depicts a view of exemplary components used to form an exemplary electronic device coupling system of the present invention. As shown in FIG. 1, exemplary electronic device coupling system 10 of the present invention comprises exemplary coupling member 11 having a front surface 6, a rear surface 7 (shown as dashed lines positioned within an interior housing volume of exemplary electronic device 12) and at least one groove 8 extending along front surface 6. Exemplary groove 8 comprises a first groove side surface 81, a second groove side surface 82 opposite first groove side surface 81, and a groove end surface 83.

As shown in FIG. 1, exemplary coupling member 11 forms at least a portion (e.g., in this exemplary embodiment, a rear portion) of an outer housing 13 of an electronic device 12. In particular, exemplary coupling member 11 forms a rear portion of outer housing 13, wherein rear housing surface 6 of electronic device 12 also represents a front surface of exemplary coupling member 11.

As shown in FIG. 1, exemplary electronic device coupling system 10 also comprises exemplary support member 2, and exemplary electronic device 12. In this exemplary embodiment, exemplary support member 2 comprises a relatively thin card-like support beam having an upper support member surface 24; a lower support member surface 25 opposite upper support member surface 24; a support member thickness, tₛ, extending between upper support member surface 24 and lower support member surface 25; a first end 22; and a second end 23 opposite first end 22. As shown in FIG. 1, a portion of first end 22, namely, first end portion 21, is positioned within exemplary groove 8 so as to support exemplary electronic device 12.

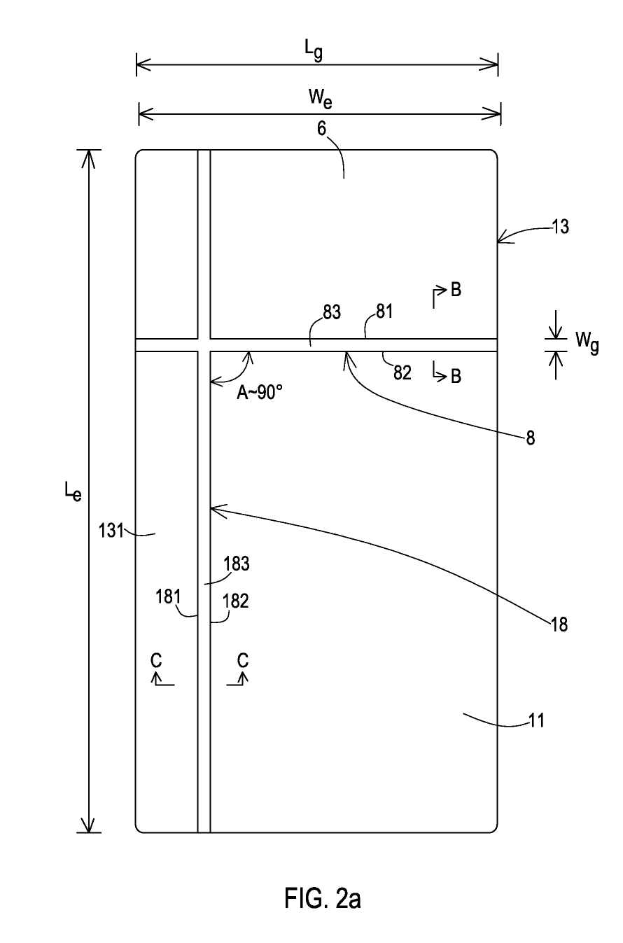

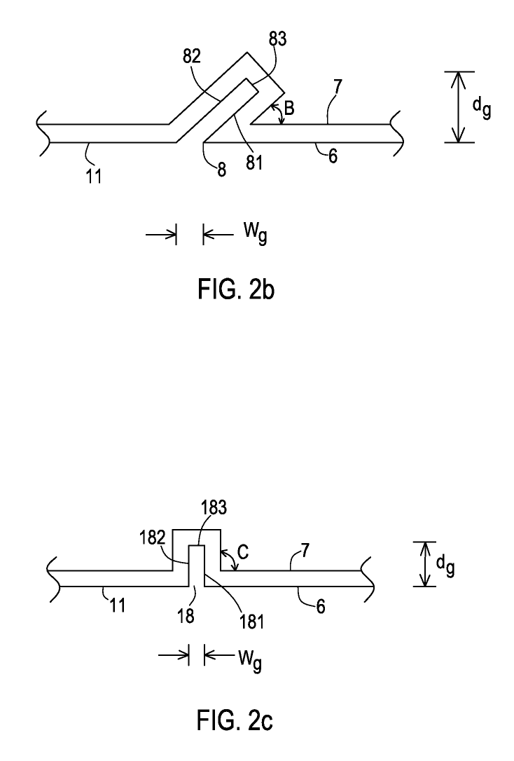

FIG. 2a depicts a rear view of exemplary coupling member 11 utilized within exemplary electronic device coupling system 10 shown in FIG. 1. As shown in FIG. 2a, exemplary coupling member 11 comprises two grooves 8 and 18 with two grooves 8 and 18 being positioned at a substantially orthogonal angle A to one another. It should be noted that when two intersecting grooves 8 and 18 are present, angle A may vary from 90° as desired. Further, when two or more grooves are present, angle A between any two adjacent intersecting grooves may vary from as little as about 10° to as much as 90°, as desired, with angle A representing the smallest angle between any two adjacent intersecting grooves. In addition, although not shown, two or more non-intersecting grooves may be present as desired.

It should be noted that when two or more grooves (e.g., two grooves 8 and 18) are present, the two or more grooves may each independently have a groove depth forming a groove angle relative to the front (and rear) surface of the coupling member (or a plane containing an outermost portion of the front surface and being parallel to rear surface 7 of exemplary coupling member 11 or a front surface 15 or exemplary electronic device 12). In one exemplary embodiment, as shown in FIGS. 2a-2c, two grooves 8 and 18 comprise (i) a first groove 8 having a first groove angle B relative to front surface 6 and rear surface 7 (i.e., with angle B representing the smallest angle between (1) either groove side surface and (2) the front or rear surface of exemplary coupling member 11 (or a plane containing an outermost portion of the front surface and being parallel to rear surface 7 of exemplary coupling member 11 or a front surface 15 or exemplary electronic device 12), (ii) a second groove 18 having a second groove angle C relative to front surface 6 and rear surface 7 with angle C representing the smallest angle between (1) either groove side surface and (2) the front or rear surface of exemplary coupling member 11 (or a plane containing an outermost portion of the front surface and being parallel to rear surface 7 of exemplary coupling member 11 or a front surface 15 or exemplary electronic device 12).

First groove angle B and second groove angle C may be identical, substantially the same, or differ from one another. In some embodiments, first groove angle B differs from second groove angle C (e.g., when supporting a rectangular shaped electronic device). Typically, each of first groove angle B and second groove angle C may each independently range from about 15° to about 90°, typically less than about 90°, relative to front surface 6 and/or rear surface 7.

FIGS. 2b-2c further show exemplary groove depths, d_{g}, and exemplary groove widths, w_{g}. It should be understood that each groove comprises a groove depth, d_{g}, and a groove width, w_{g}, sized so that a portion of a support member (e.g., first end portion 21 of support member 2) can extend within the groove and support an object (e.g., exemplary electronic device 12) onto which is attached a given coupling member (e.g., exemplary coupling member 11). Typically, groove depths, d_{g}, range from about 0.125 inches (in.) to about 2.0 in., and groove widths, w_{g}, range from about 0.015 in. to about 0.5 in., depending on the size of the object to be supported (e.g., a cell phone versus a personal computer).

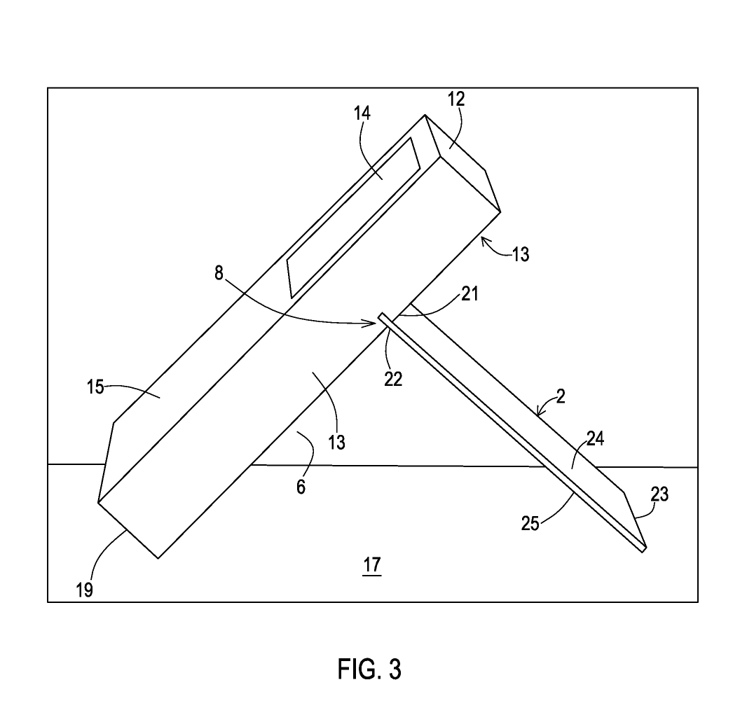

FIG. 3 depicts a side view of exemplary coupling member 11 shown in FIG. 2a positioned in an upright position along flat surface 17 with exemplary support member 2 positioned within groove 8 of exemplary coupling member 11. As shown in FIG. 3, exemplary electronic device 12 comprises outer housing 13 having front housing surface 15 with screen display 14 positioned therein, and a lower side housing surface 19 proximate flat surface 17.

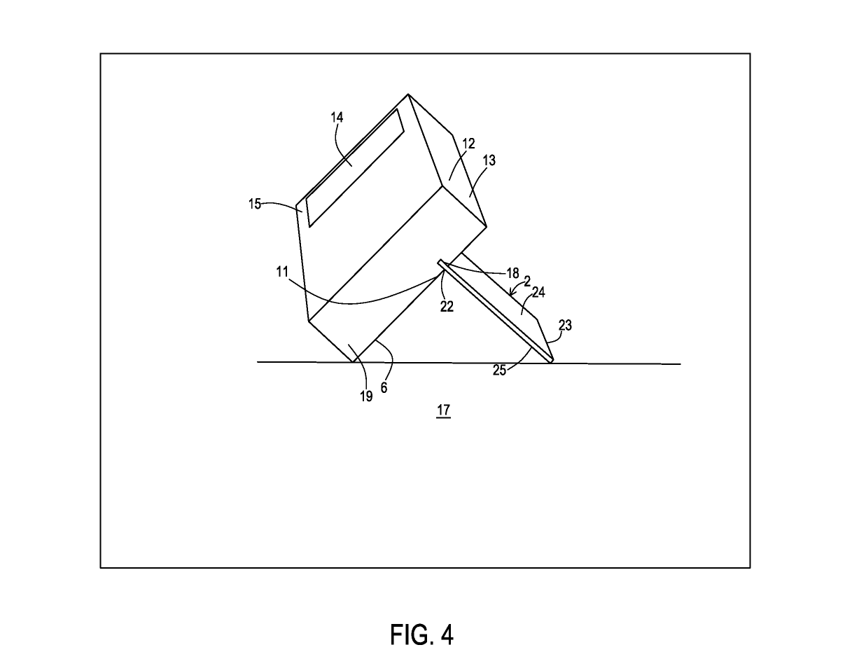

FIG. 4 depicts a side view of exemplary coupling member 11 shown in FIG. 2a positioned along flat surface 17 in a horizontal position with exemplary support member 2 positioned within groove 18 of exemplary coupling member 11. As shown in FIG. 4, exemplary electronic device 12 comprises outer housing 13 having front housing surface 15 with screen display 14 positioned therein, and a lower side housing surface 19 positioned orthogonal to flat surface 17.

As shown in FIGS. 1-4, some coupling members of the present invention, such as exemplary coupling member 11, comprise or represent a rear housing portion of an outer housing (e.g., a portion of rear housing surface 6 of exemplary housing 13 of electronic device 12). In these exemplary embodiments, the one or more grooves that are present, for example, exemplary grooves 8 and 18, extend along front surface 6 of exemplary coupling member 11.

It should be noted that although exemplary coupling member 11 shows two grooves, exemplary grooves 8 and 18, any of the coupling members of the present invention may comprise as little as one groove and as many grooves as desired, typically, less than about 12 grooves. Further, although each of exemplary grooves 8 and 18 are shown as having groove lengths, L_{g} (see, FIG. 2a), that extend across a complete length (Lₑ) or width (wₑ) of exemplary electronic device 12, any given groove may have a length that is less than, or substantially less than, a complete length (Lₑ) or width (wₑ) of exemplary electronic device 12. Typically, any given groove has a length ranging from about 0.25 in. to a complete length (Lₑ) or width (wₑ) of exemplary electronic device 12, in some cases, as much as about 6.0 in.

As further shown in FIGS. 1-4, when used in combination with exemplary electronic device 12, each of (i) first groove side surface 81, (ii) second groove side surface 82 and (iii) groove end surface 83 (and (i) first groove side surface 181, (ii) second groove side surface 182 and (iii) groove end surface 183 of groove 18) extend along an outer surface 131 of outer housing 13 of electronic device 12 (i.e., front surface 6 of exemplary coupling member 11 and outer surface 131 of outer housing 13 are the same or abuts one another). Desirably, when used in combination with electronic device 12, exemplary coupling member 11 with at least one groove (e.g., grooves 8 and 18) does not increase an overall thickness, tₑ, of electronic device 12. In some embodiments, electronic device 12 comprises one or more electronic components (not shown) positioned within electronic device 12 so as to accommodate at least one groove (e.g., grooves 8 and 18). In particular, electronic device 12 comprises one or more electronic components (not shown) strategically positioned within outer housing 13 of electronic device 12 so that the at least one groove (e.g., grooves 8 and 18) extends within, in some cases, a groove depth substantially equal to overall thickness, tₑ, of electronic device 12 and between the one or more electronic components (not shown), as needed, to enable a minimum overall thickness for electronic device 12.

In some embodiments, when used in combination with electronic device 12, exemplary coupling member 11 with at least one groove (e.g., grooves 8 and 18) desirably (a) does not increase an overall thickness of electronic device 12, and (b) has a groove depth, d_{g}, that is at least 50% of an overall thickness, tₑ, of electronic device 12. Typically, groove depth, d_{g}, is equal to or greater than about 50% of an overall thickness, tₑ, of electronic device 12 up to about the overall thickness, tₑ, of electronic device 12. In some embodiments, groove depth, d_{g}, is from about 50% to about 95% of the overall thickness, tₑ, of electronic device 12.

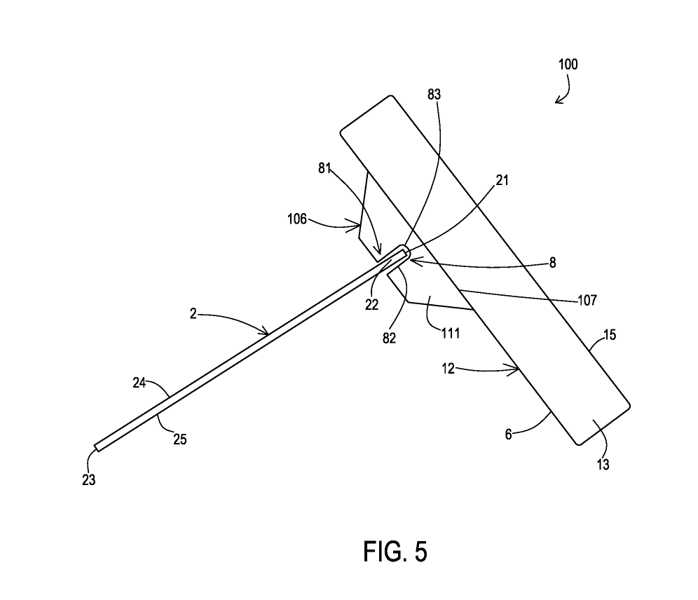

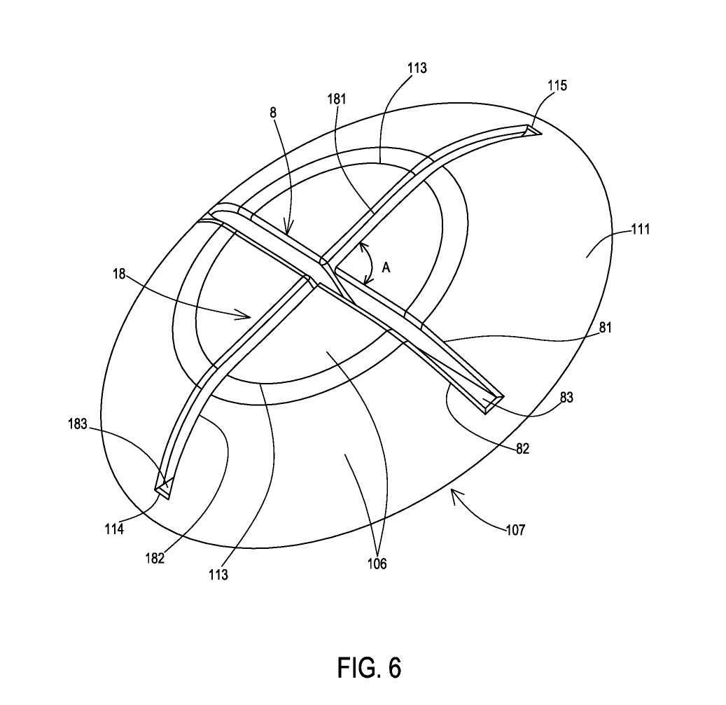

FIG. 5 depicts a view of exemplary components used to form another exemplary electronic device coupling system of the present invention. As shown in FIG. 5, exemplary electronic device coupling system 100 of the present invention comprises exemplary coupling member 111 having a front surface 106, a rear surface 107 and at least one groove 8 extending along front surface 106. In this embodiment, exemplary coupling member 111 is attachable to at least a portion (e.g., in this exemplary embodiment, a rear portion) of outer housing 13 of electronic device 12.

FIG. 6 depicts a frontal perspective view of exemplary coupling member 111 utilized in exemplary electronic device coupling system 100 shown in FIG. 5. As shown in FIG. 6, exemplary coupling member 111 comprises two grooves 8 and 18 with two grooves 8 and 18 being positioned at a substantially orthogonal angle A to one another. As discussed above, when two intersecting grooves 8 and 18 are present, angle A may vary from 90° as desired. As further discussed above, each of grooves 8 and 18 may independently comprise (i) a first groove angle (e.g., angle B) relative to rear surface 107, and (ii) a second groove angle (e.g., angle C) relative to rear surface 107. First groove angle (e.g., angle B) and second groove angle (e.g., angle C) may be equal or differ from one another.

As shown in FIG. 6, exemplary grooves 8 and 18 extend across a full length and width of exemplary coupling member 111. For example, exemplary groove 18 extends from point 114 to point 115 along front surface 106. However, it should be noted that each groove (e.g., each of exemplary grooves 8 and 18 independent of one another) may have a groove length that is as little as about 0.25 in. up to a complete length or width of a given coupling member (e.g., exemplary coupling member 111). For example, in an alternative embodiment, exemplary groove 18 may only extend within circle 113 along front surface 106.

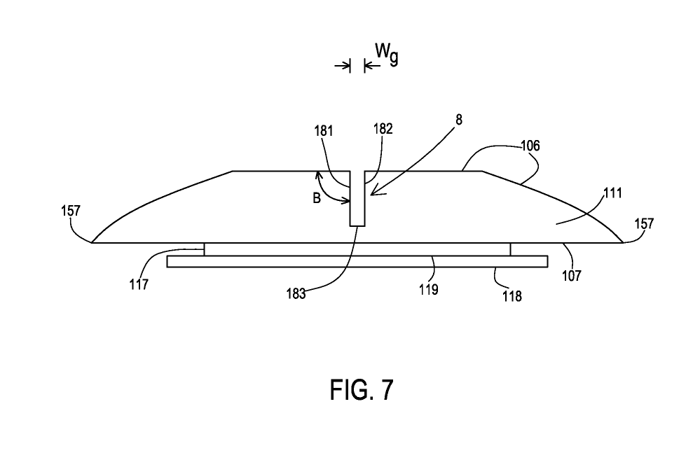

Exemplary coupling member 111 further comprises an attachment member positioned along rear surface 107, wherein the attachment member is operatively adapted and sized to attach exemplary coupling member 111 to an outer housing surface of an electronic device (e.g., outer rear housing surface 6 of outer housing 13 of electronic device 12). FIG. 7 depicts a side view of exemplary coupling member 111 showing exemplary attachment member 117.

As shown in FIG. 7, exemplary attachment member 117 is positioned along rear surface 107 and within an outer periphery 157 of exemplary coupling member 111. Exemplary attachment member 117 may comprise any material that enables exemplary coupling member 111 to be attached to an outer housing surface of an electronic device (e.g., outer rear housing surface 6 of outer housing 13 of electronic device 12). Suitable materials include, but are not limited to, chemical compositions including adhesives such as pressure-sensitive adhesives; mechanical structures such as hook and loop material, screws, etc.; and magnetism. In one desired embodiment, shown in FIG. 7, exemplary attachment member 117 comprises an adhesive layer (e.g., a pressure-sensitive adhesive layer 117). In this embodiment, exemplary coupling member 111 further comprises a removable release liner 118 positioned along an outer surface 119 of adhesive layer 117.

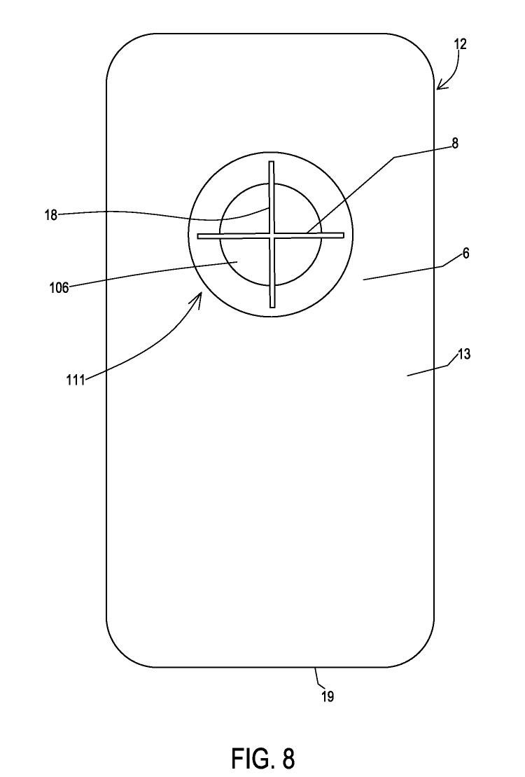

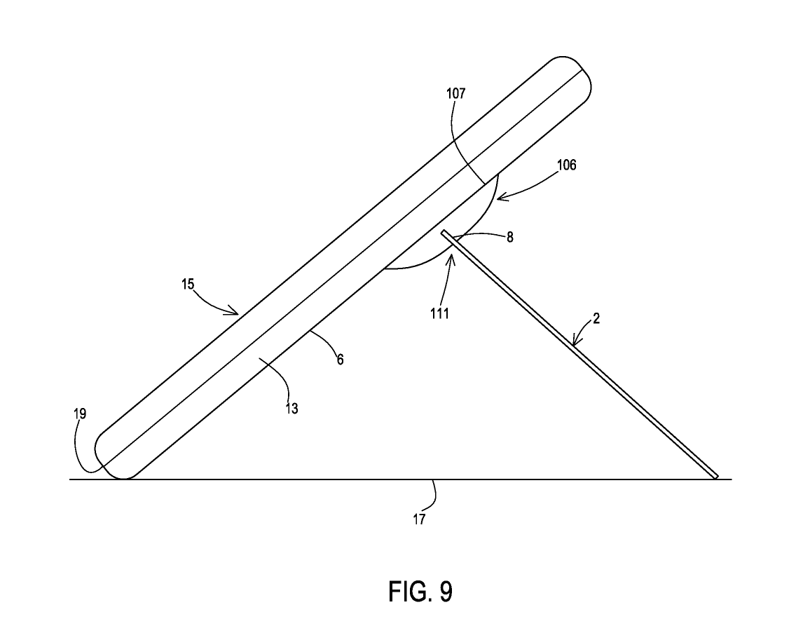

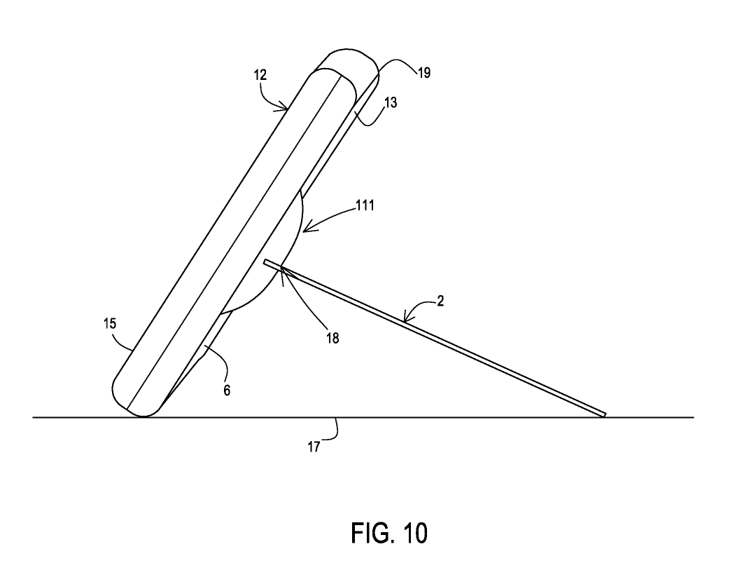

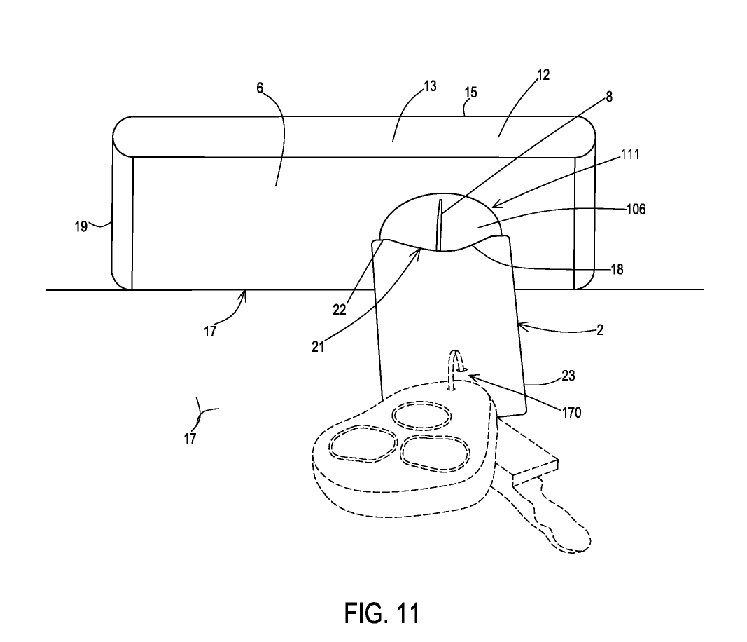

FIG. 8 depicts a view of exemplary coupling member 111 shown in FIG. 6 attached to rear surface 6 of exemplary electronic device 12. FIG. 9 depicts a side view of exemplary coupling member 111 in combination with exemplary electronic device 12 and supported by exemplary support member 2 in an upright position. FIG. 10 depicts a side view of exemplary coupling member 111 in combination with exemplary electronic device 12 and supported by exemplary support member 2 in a horizontal position. FIG. 11 depicts a rear view of exemplary coupling member 111 in combination with exemplary electronic device 12 and exemplary support member 2 in a horizontal position, and relative to key chain 170.

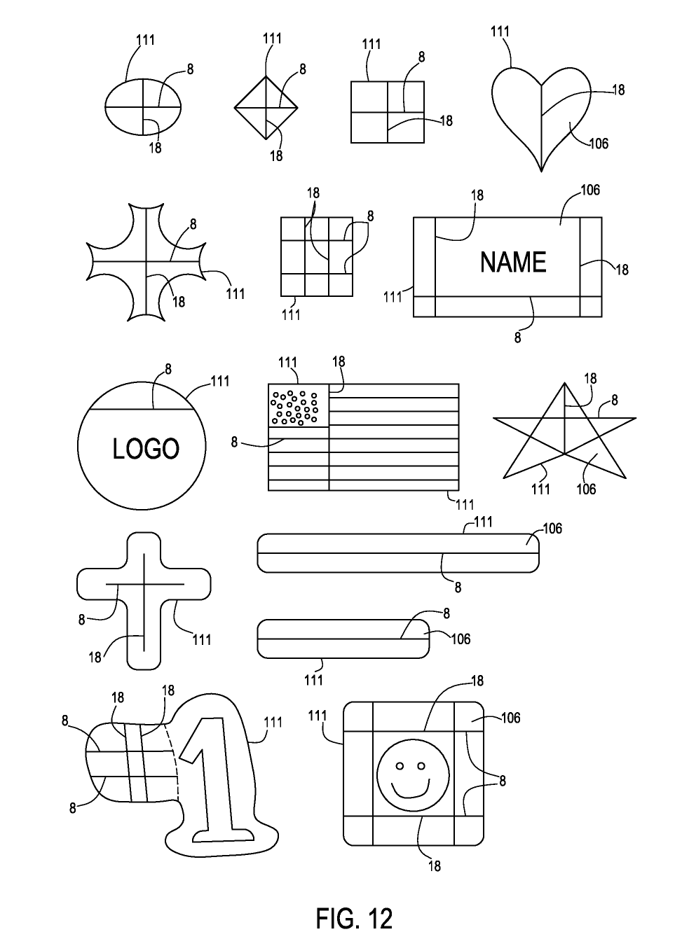

FIG. 12 depicts frontal views of exemplary shapes of fifteen exemplary coupling members suitable for use in exemplary electronic device coupling systems 10 and 100 shown in FIGS. 1-2. In other words, any of the fifteen exemplary coupling members 111 may be formed so as to (1) represent a portion of the outer housing of an object to be supported (e.g., a rear portion of exemplary outer housing 13 of electronic device 12 shown in exemplary electronic device coupling system 10 in FIG. 1) or (2) be attachable to at least a portion of the housing of an object to be supported (e.g., be attachable to a rear portion of exemplary outer housing 13 of electronic device 12 shown in exemplary electronic device coupling system 100 in FIG. 5).

Each of the fifteen exemplary coupling members 111 shown in FIG. 12 comprises one or more grooves 8 and/or 18 along front surface 106. Further, when used in combination with an electronic device (e.g., electronic device 12), each of the one or more grooves 8 and/or 18 extends along a rear housing surface of the electronic device with each of the first groove side surface(s), the second groove side surface(s), and the groove end surface(s) forming inner surfaces of exemplary coupling members 111.

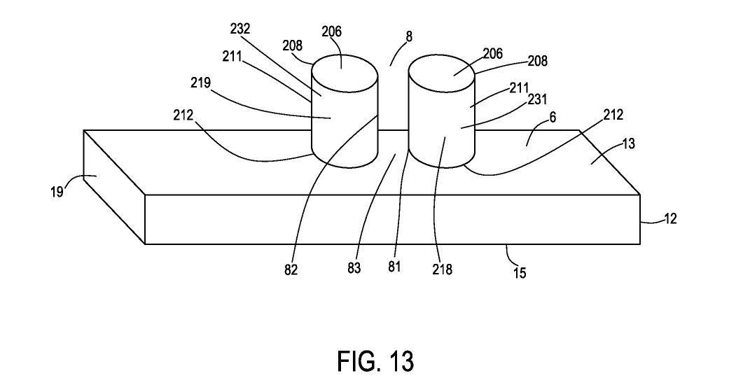

FIG. 13 depicts a frontal perspective view of another exemplary coupling member suitable for use in exemplary electronic device coupling systems 10 and 100 shown in FIGS. 1-2. In other words, exemplary coupling members 211 may be formed so as to (1) represent a portion of the outer housing of an object to be supported (e.g., an extension to a rear portion of exemplary outer housing 13 of electronic device 12 shown in exemplary electronic device coupling system 10 in FIG. 1) or (2) be attachable to at least a portion of the housing of an object to be supported (e.g., be attachable to a rear portion of exemplary outer housing 13 of electronic device 12 shown in exemplary electronic device coupling system 100 in FIG. 5).

As shown in FIG. 13, exemplary coupling member 211 comprises a pair of coupling members 211, each of which has a front surface 206 along front end 208, and an opposite end 212 positioned along rear surface 6 of outer housing 13 of electronic device 12. When pair of coupling members 211 are integrally formed as an extension of rear surface 6 of outer housing 13 of electronic device 12, a rear surface of pair of coupling members 211 is represented by an inner housing surface (not shown) positioned within outer housing 13 (see, for example, rear surface 7 shown in FIG. 1). When pair of coupling members 211 are attached to rear surface 6 of outer housing 13 of electronic device 12, a rear surface of pair of coupling members 211 is represented by rear surface 207 in contact with an outer surface of outer housing 13 (e.g., rear housing surface 6) via an attachment member (see, discussion above).

As further shown in FIG. 13, in this embodiment, groove 8 extends between the pair of coupling members 211 such that first groove side surface 81 is along a side surface 218 of a first coupling member 231 of the pair of coupling members 211, second groove side surface 82 is along a side surface 219 of a second coupling member 232 of the pair of coupling members 211, and groove end surface 83 is along rear housing surface 6 between the pair of coupling members 211.

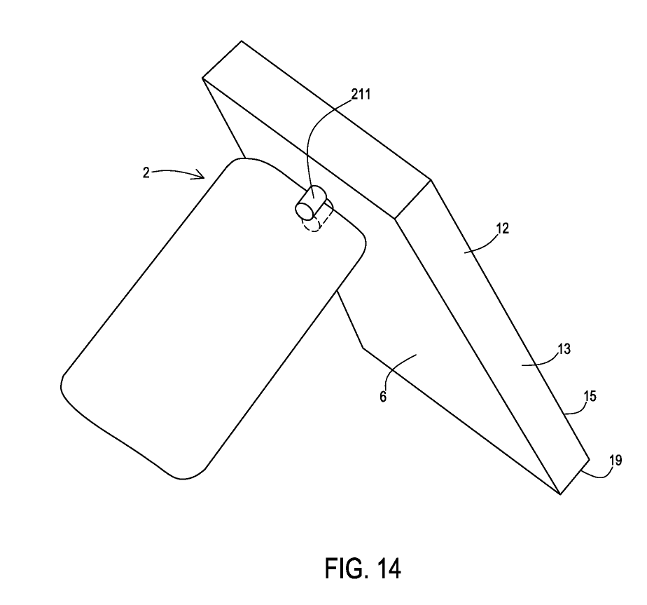

FIG. 14 depicts a rear perspective view of exemplary coupling member 211 shown in FIG. 13 attached to rear surface 6 of exemplary electronic device 12 and supported by exemplary support member 2 in an upright position.

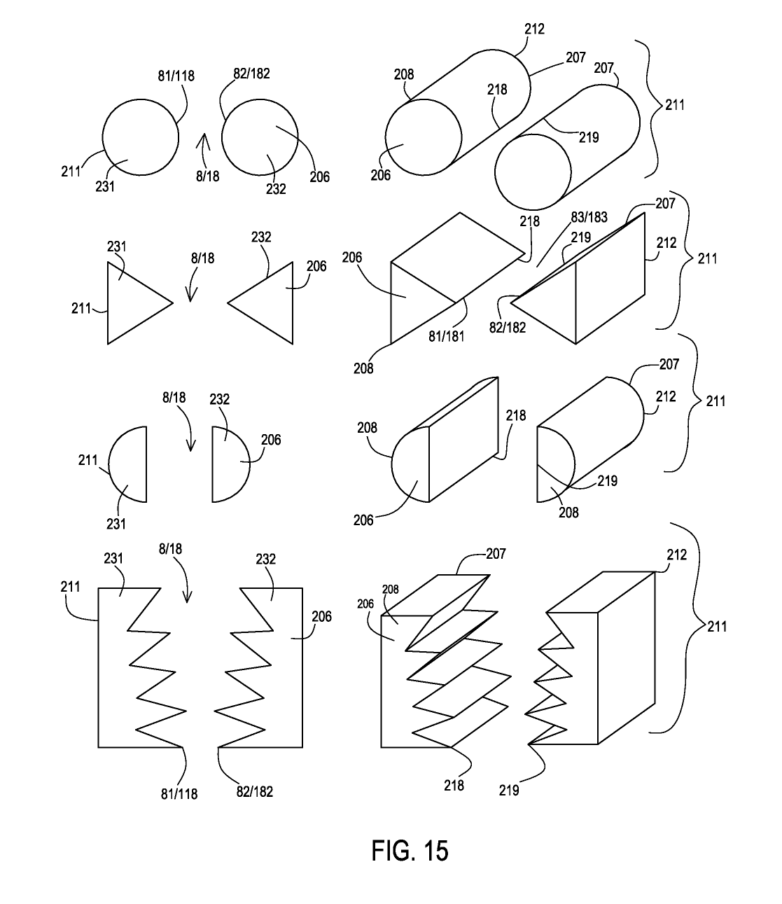

FIG. 15 depicts various exemplary shapes for four exemplary coupling members suitable for use in the exemplary electronic device coupling systems shown in FIGS. 1-2. In other words, each pair of exemplary coupling members 211 may be formed so as to (1) represent a portion of the outer housing of an object to be supported (e.g., an extension to a rear portion of exemplary outer housing 13 of electronic device 12 shown in exemplary electronic device coupling system 10 in FIG. 1) or (2) be attachable to at least a portion of the housing of an object to be supported (e.g., be attachable to a rear portion of exemplary outer housing 13 of electronic device 12 shown in exemplary electronic device coupling system 100 in FIG. 5) via an attachment member as discussed above.

As shown in FIG. 15, each pair of coupling members 211 comprises front surface 206 along front end 208, and an opposite end 212. When a given pair of coupling members 211 are integrally formed as an extension of rear surface 6 of outer housing 13 of electronic device 12, a rear surface of any pair of coupling members 211 is represented by an inner housing surface (not shown) positioned within outer housing 13 (see, for example, rear surface 7 shown in FIG. 1). When a given pair of coupling members 211 are attached to rear surface 6 of outer housing 13 of electronic device 12, a rear surface of each pair of coupling members 211 is represented by rear surface 207 (as shown in FIG. 15) in contact with an outer surface of outer housing 13 (e.g., rear housing surface 6) via an attachment member (see, discussion above).

As further shown in FIG. 15, exemplary grooves 8 and/or 18 extend between each pair of coupling members 211 such that first groove side surface 81 or 181 is along side surface 218 of first coupling member 231 of the pair of coupling members 211, second groove side surface 82 or 182 is along side surface 219 of second coupling member 232 of the pair of coupling members 211, and groove end surface 83 or 183 is along rear housing surface 6 between the pair of coupling members 211.

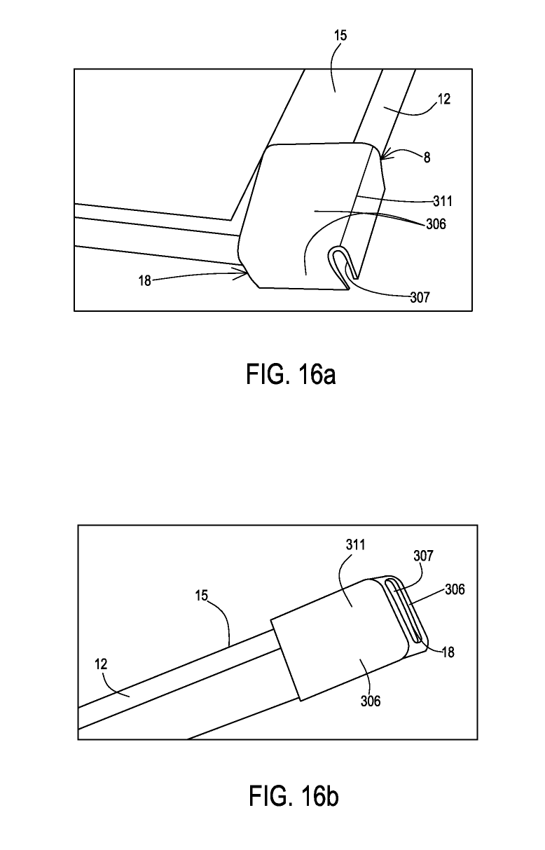

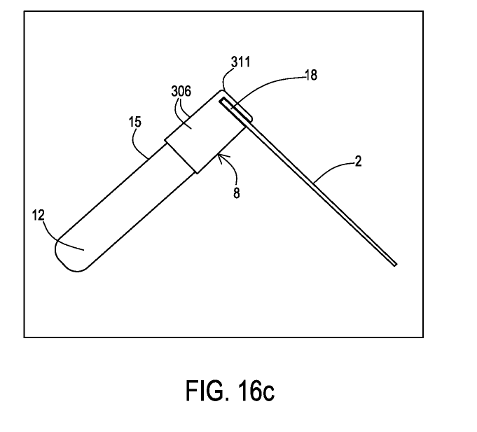

FIGS. 16a-16c depict frontal and side views of another exemplary coupling member 311 suitable for use in exemplary electronic device coupling systems 10 and 100 shown in FIGS. 1-2. In other words, exemplary coupling member 311 may be formed so as to (1) represent a portion of the outer housing of an object to be supported (e.g., an extension of an edge portion of exemplary outer housing 13 of electronic device 12 shown in exemplary electronic device coupling system 10 in FIG. 1) or (2) be attachable to at least a portion of the housing of an object to be supported (e.g., be attachable to a front portion of exemplary outer housing 13 of electronic device 12 shown in exemplary electronic device coupling system 100 in FIG. 5) via an attachment member as discussed above.

As shown in FIGS. 16a-16c, exemplary coupling member 311 comprises front surface 306, and a rear surface 307 opposite front surface 306. When exemplary coupling member 311 is integrally formed as an extension of an edge of outer housing 13 of electronic device 12, exemplary coupling member 311 comprises an outer edge portion of outer housing 13 of electronic device 12, and each of the one or more grooves extends along rear surface 307 of exemplary coupling member 311. When in combination with electronic device 12 (i.e., exemplary coupling member 311 is integrally attached to electronic device 12), each of the one or more grooves (see, grooves 8 and 18 in FIGS. 16a-16c) extends along a rear outer edge of electronic device 12 with each of (i) first groove side surface(s) 81 and/or 181, (ii) second groove side surface(s) 82 and/or 182 and (iii) groove end surface(s) 83 and/or 183 extend along an outer surface (e.g., rear outer housing surface 6) of outer housing 13 of electronic device 12.

When exemplary coupling member 311 is attachable to outer housing 13 (e.g., front surface 15) of electronic device 12 via an attachment member so as to represent an extension of an edge of outer housing 13 of electronic device 12, each of the one or more grooves (see, grooves 8 and 18 in FIGS. 16a-16c) extends along rear surface 307 of exemplary coupling member 311. When in combination with electronic device 12, each of the one or more grooves (see, grooves 8 and 18 in FIGS. 16a-16c) extends along one or more rear outer edges of electronic device 12 with (i) each of first groove side surface(s) 81 and/or 181 and each of groove end surface(s) 83 and/or 183 extending along rear surface 307 of exemplary coupling member 311, while (ii) each of second groove side surface(s) 82 and/or 182 extend along an outer side (edge) surface of outer housing 13 of electronic device 12.

Although not shown in FIGS. 16a-16c, when exemplary coupling member 311 is attached to electronic device 12, exemplary coupling member 311 comprises an attachment member, such as exemplary attachment member 117 shown in FIG. 7. Any of the above-described attachment members may be used in combination with exemplary coupling member 311. Desirably, exemplary coupling member 311 comprises an adhesive layer (e.g., a pressure-sensitive adhesive layer 117) along rear surface 307 of exemplary coupling member 311 temporarily covered with a removable release liner such as removable release liner 118 shown in FIG. 7.

The electronic device coupling systems of the present invention may comprise one or more of the herein described coupling members in combination with (1) one or more electronic devices; (2) one or more support members; (3) one or more outer housing components (e.g., a housing backing, a housing component comprising a housing opening sized for placement of a screen display therein, a battery housing cover, etc.); or (4) any combination of (1) to (3). In one desired embodiment, the electronic device coupling systems of the present invention comprise one or more of the herein described coupling members in combination with one or more electronic devices. Suitable electronic devices include, but are not limited to, hand-held devices such as a cellular phone, a smart phone, an electronic computer pad, an electronic game player, a computer, a video player, and an audio player. Other suitable electronic devices include, but are not limited to, a personal computer, a video display for a personal computer, etc.

Although not limited to any particular dimensions, the electronic device coupling systems of the present invention may, for example, be used to support an electronic device (e.g., exemplary electronic device 12) having dimensions of from about 2.5 in. in width, about 4.5 in. in length, and about 0.5 in. in thickness (e.g., similar to the dimensions of a smart phone). A support member having dimensions of about 3.5 in. in width, 2 in. in length, and 0.030 in. in thickness (e.g., similar in size to a credit card) may be used in combination with a compatibly sized coupling member, such as one of the above-described coupling member (e.g., exemplary coupling members 11, 111, 211, and/or 311). For example, the coupling member may be integrally connected to the rear of the electronic device so as to form a rear surface of the electronic device with a groove extending thru the front surface of the coupling member, the groove having a groove width of the support member plus about 5 percent (or a groove width equal to a thickness of the support member), or about 0.0315 in., and a groove depth of about half the thickness (or up to 100% of the thickness) of the electronic device.

Support member 2, described in the figures above, may be about the size and thickness of a credit card. Other common plastic cards suitable for use as support member 2 include, but are not limited to, debit card, gift card, rewards card, membership card, driver's license, hotel key card, and others. In addition to common plastic cards, other suitable support members 2 include, but are not limited to, key-tags, business cards, and any other object that is sufficiently rigid, properly sized, and able to fit between the support surfaces (e.g., groove surfaces 81 and 82) of a groove within the coupling member may be used as a support beam.

The coupling member cooperating surfaces (e.g., groove surfaces 81, 82 and 83) are typically formed flat, smooth, approximately parallel to each other, and oriented approximately perpendicular to the rear of the electronic device (i.e., angle B or C=90); however, as discussed above, the coupling member cooperating surfaces (e.g., groove surfaces 81 and 82) may form any desired angle with the rear of the electronic device (e.g., angle B or C<90). In addition to approximately parallel opposing groove surfaces, the coupling member cooperating surfaces (e.g., groove surfaces 81 and 82) may also be curved or converging so that the support member is retained between the opposing surfaces through friction. Further, coupling member cooperating surfaces (e.g., groove surfaces 81 and 82) may also be of other forms and orientations, such as curved, rounded, pointed, triangular, textured, wavy, and/or angled, with opposing surfaces (e.g., groove surfaces 81 and 82) in a parallel or non-parallel relationship relative to one another.

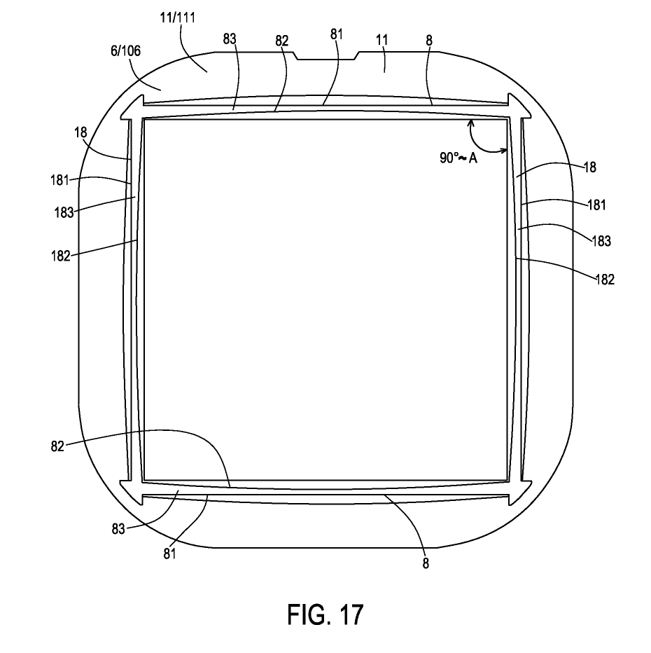

FIG. 17 depicts exemplary coupling member 11/111 suitable for use in exemplary electronic device coupling systems 10/100 shown in FIGS. 1-2, wherein grooves have one or more curved groove surfaces. As shown in FIG. 17, grooves 8 and 18 (represented by the orange color) each comprise a straight groove surface 81/181 in combination with a curved (non-parallel) surface 82/182 opposite straight groove surface 81/181. As shown in FIG. 17, and similar to the discussion above with regard to exemplary grooves 8 and 18 in FIG. 6, each of exemplary grooves 8 and 18 (represented by the orange color) extend less than a complete length and width of coupling member 11/111, although in some embodiments, grooves 8 and 18 may extend a complete length and/or a complete width of a given coupling member.

Although each of exemplary grooves 8 and 18 shown in FIG. 17 (represented by the orange color) are shown as comprising straight groove surface 81/181 in combination with a curved (non-parallel) surface 82/182 opposite straight groove surface 81/181, groove surfaces 81/181 in combination with opposing groove surfaces 82/182 may comprise any combination of (i) straight parallel surfaces, (ii) one straight and one curved (non-parallel) surface, (iii) curved parallel surfaces (e.g., an equal distance from one surface location to an opposing surface location along a length of each surface), and/or (iv) curved non-parallel surfaces (e.g., a varying distance from one surface location to an opposing surface location along a length of each surface), with the term “curved” surface representing any surface other than a straight surface, e.g., angled, wavy, etc.

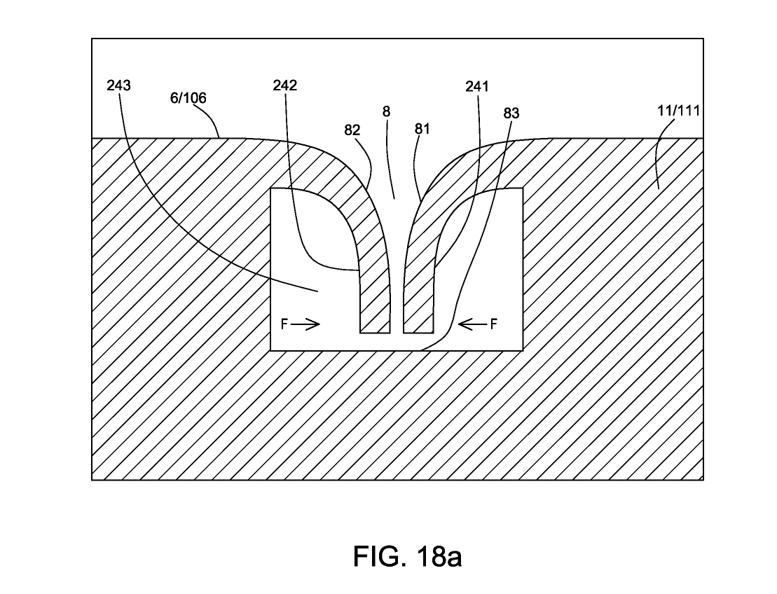

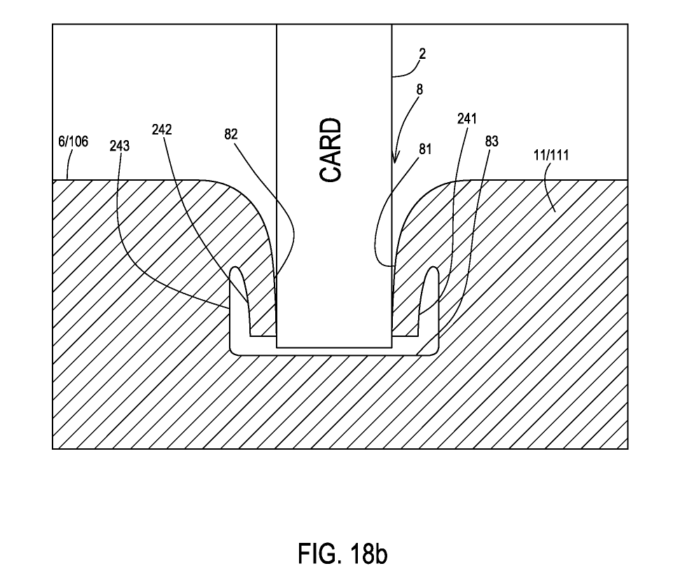

Further, although each of exemplary grooves 8 and 18 shown in FIG. 17 (represented by the orange color) as comprising groove surfaces 81/181 in combination with opposing groove surfaces 82/182 distanced from one another (i.e., have a groove width, w_{g}, therebetween as shown above and discussed, for example, in reference to FIGS. 2b-2c), in some exemplary embodiments, opposing groove surfaces 81/181 and 82/182 may be in contact with one another and move relative to one another when separated with a support member (e.g., exemplary support member 2). Such a groove configuration is shown in FIGS. 18a-18b.

As shown in FIGS. 18a-18b, exemplary coupling member 11/111 comprises movable groove members 241 and 242 extending into a groove cavity 243 proximate outer surface 6/106 of exemplary coupling member 11/111. Opposing groove surfaces 81 and 82 are represented by opposing outer surfaces of movable groove members 241 and 242, while groove end surface 83 is represented by an innermost surface of groove cavity 243 shown in FIGS. 18a-18b as being substantially parallel to outer surface 6/106 of exemplary coupling member 11/111.

As shown in FIG. 18a, movable groove members 241 and 242 (and opposing groove surfaces 81 and 82) are in contact with one another. In this configuration, exemplary groove 8 is said to be in a “closed” configuration. Movable groove members 241 and 242 are typically manufactured so as to remain in contact with one another as shown by arrows F until a force is exerted onto movable groove members 241 and 242 so as to separate movable groove members 241 and 242 (and opposing groove surfaces 81 and 82) from one another.

As shown in FIG. 18b, movable groove members 241 and 242 (and opposing groove surfaces 81 and 82) are separated from one another by exemplary support member 2 (e.g., a credit card) positioned therebetween. In this configuration, exemplary groove 8 is said to be in an “open” configuration. Once exemplary support member 2 (e.g., a credit card) is removed from groove 8, movable groove members 241 and 242 (and opposing groove surfaces 81 and 82) typically return to the “closed” configuration shown in FIG. 18a.

As shown in the figures above, exemplary grooves (e.g., exemplary grooves 8 and 18) may, when in a “relaxed” state, be in contact with one another or may have a groove width, w_{g}, therebetween. As discussed above, opposing groove surfaces may be configured so as to have (i) an equal distance between opposing groove surface locations along a length of a given groove, or (ii) a varying distance between opposing groove surface locations along a length of a given groove, Even when configured as shown in FIGS. 18a-18b, opposing groove surfaces 81 and 82 positioned along movable groove members 241 and 242 may be configured so as to have (i) an equal distance between opposing groove surface locations along a length of a given groove (i.e., opposing groove surfaces 81 and 82 of movable groove members 241 and 242 are in contact with one another along a width of each of movable groove members 241 and 242), or (ii) a varying distance between opposing groove surface locations along a length of a given groove (i.e., opposing groove surfaces 81 and 82 of movable groove members 241 and 242 are in contact with one at one or more contact points along a width of each of movable groove members 241 and 242, but not in contact with one another along a width of each of movable groove members 241 and 242).

According to one exemplary embodiment of the present invention, an electronic device coupling system designed to accommodate and retain a credit card along one edge, may fit within the dimensions of a groove positioned along an outer surface of a smart phone cellular telephone. Equipping, for example, the rear of a smart phone with a coupling member allows a credit card to be utilized as a rearward extending support beam for standing the smart phone at a rearward eased angle up from a horizontal surface in a position that may allow for improved viewing the front of the smart phone. As discussed above, the groove may be (i) a straight groove such that the credit card fits within the groove without altering the credit card, or (ii) a curved groove that requires the credit card to be altered slightly so as to fit within the groove.

The coupling member allows for removably coupling a credit card to a smart phone by the cooperation a supporting surface and a retaining surface arranged opposite from one another (e.g., first and second groove surfaces 81 and 82) and disposed upon and accessible from the rear of a smart phone. The coupling member allows insertion of a credit card to a depth of at least the thickness of the credit card, and, in some embodiments, preferably about three times the thickness of a credit card. The distance between groove supporting surface and groove retaining surface (e.g., first and second groove surfaces 81 and 82) is close enough to engage each side of the support beam during operation, and in one exemplary embodiment, the distance may be about the thickness of a credit card (optionally, the thickness of a credit card plus about 5 percent) and allows easy insertion and removal of a credit card when the weight of the smart phone is relieved. Although there is no limitation on the groove width (i.e., a groove width in an “open” configuration or a groove width as shown in FIGS. 2b-2c), typically, the groove width may range from 0.015 in. to as much as 0.25 in., and in some cases, the groove width is substantially equal to the thickness of a credit card, namely, about 0.030 in.

In operation, the credit card may be coupled by leverage between the supporting surface and the retaining surface (e.g., first and second groove surfaces 81 and 82) applied by the weight of a smart phone leaning rearward up from a horizontal surface. The coupled credit card acting as a cantilever extended rearward from the smart phone may be capable of supporting the smart phone at a rearward eased angle up from a horizontal surface when the free end of the coupled credit card cantilever contacts the same horizontal surface.

The present invention is further directed to methods of making any of the herein described electronic device coupling systems and the components used therein. Suitable methods include, but are not limited to, thermoforming any one of the herein-described electronic device coupling system components; thermoforming any other components (e.g., the remaining outer housing components of an electronic device); and assembling the coupling system components with one another and with other components (e.g., the remaining outer housing components of an electronic device).

Electronic device coupling system components may be molded, machined, formed, stamped, created or crafted in any way and with any material. Suitable materials include, but are not limited to, plastics, metals, ceramics, or any other material that is suitable in the operation of the herein-described electronic device coupling system.

The present invention is even further directed to methods of using electronic device coupling systems to removably couple a support beam or member to an electronic device, such as a hand-held electronic device (e.g., a cellular phone). In one exemplary embodiment, the method of supporting an electronic device comprises inserting a card between the bearing surface and retaining surface (e.g., first and second groove surfaces 81 and 82) of a coupling member (e.g., exemplary coupling member 11, 111, 211, and/or 311) for removably coupling a support beam (e.g., support member 2) to the electronic device, thereby forming an assembled cantilever beam extending from the electronic device and then placing the assembly onto a horizontal surface so that the free end of the cantilever beam and one side of the electronic device contact the surface.

In another exemplary embodiment, a method of supporting an electronic device comprises inserting a card between the bearing surface and retaining surface (e.g., first and second groove surfaces 81 and 82) of a coupling member which forms an outer housing component of an electronic device (e.g., exemplary coupling member 11, 211, and/or 311) for removably coupling a support beam (e.g., support member 2) to the electronic device, thereby forming an assembled cantilever beam extending from the electronic device and then placing the assembly onto a horizontal surface so that the free end of the cantilever beam and one side of the electronic device contact the surface.

While the specification has been described in detail with respect to specific embodiments thereof, it will be appreciated that those skilled in the art, upon attaining an understanding of the foregoing, may readily conceive of alterations to, variations of, and equivalents to these embodiments. Accordingly, the scope of the present invention should be assessed as that of the appended claims and any equivalents thereto.

What is claimed is:

1. An electronic device coupling system comprising:
an outer housing for an electronic device; and
a coupling member having a front surface, a rear surface, and at least one groove extending along (i) said front surface, (ii) said rear surface or (iii) both of said front and rear surfaces, each of said at least one groove comprising a first groove side surface, a second groove side surface opposite said first groove side surface, and a groove end surface;
wherein said coupling member either (i) forms at least a portion of said outer housing or (ii) is attachable to at least a portion of said outer housing.

2. The electronic device coupling system of claim 1, wherein said coupling member forms at least a portion of said outer housing.

3. The electronic device coupling system of claim 2, wherein said coupling member comprises two grooves with said two grooves being positioned at a substantially orthogonal angle to one another.

4. The electronic device coupling system of claim 3, wherein said two grooves comprise (i) a first groove having a first groove angle relative to said rear surface, (ii) a second groove having a second groove angle relative to said rear surface, and wherein said first groove angle differs from said second groove angle.

5. The electronic device coupling system of claim 2, wherein said coupling member comprises a rear housing portion of said outer housing; and when used in combination with the electronic device, each of (i) said first groove side surface, (ii) said second groove side surface and (iii) said groove end surface extend along an outer surface of said outer housing of said electronic device.

6. The electronic device coupling system of claim 5, in combination with the electronic device, wherein said at least one groove does not increase an overall thickness of said electronic device, and said electronic device comprises one or more electronic components positioned within said outer housing of said electronic device so as to accommodate said at least one groove.

7. The electronic device coupling system of claim 5, in combination with the electronic device, wherein said at least one groove (a) does not increase an overall thickness of said electronic device, and (b) has a groove depth that is as much as 50% of an overall thickness of said electronic device.

8. The electronic device coupling system of claim 2, wherein said coupling member comprises an outer edge portion of said outer housing; each of said at least one groove (a) extends along said rear surface of said coupling member, and when used in combination with the electronic device, (b) extends along a rear outer edge of said outer housing of said electronic device with each of (i) said first groove side surface, (ii) said second groove side surface and (iii) said groove end surface extends along an outer surface of said outer housing of said electronic device.

9. The electronic device coupling system of claim 8, in combination with the electronic device, wherein said at least one groove (a) does not increase an overall thickness of said electronic device, and (b) has a groove depth that is as much as at least 75% of an overall thickness of said electronic device.

10. The electronic device coupling system of claim 1, wherein said coupling member is attachable to at least a portion of said outer housing.

11. The electronic device coupling system of claim 10, wherein said coupling member comprises two grooves with said two grooves being positioned at a substantially orthogonal angle to one another.

12. The electronic device coupling system of claim 11, wherein said two grooves comprise (i) a first groove having a first groove angle relative to said rear surface, (ii) a second groove having a second groove angle relative to said rear surface, and wherein said first groove angle differs from said second groove angle.

13. The electronic device coupling system of claim 10, wherein said coupling member further comprises an attachment member positioned along said rear surface, said attachment member being operatively adapted and sized to attach to said outer housing surface of an electronic device.

14. The electronic device coupling system of claim 13, wherein said attachment member comprises adhesive, and said coupling member further comprises a removable release liner positioned along an outer surface of said adhesive.

15. The electronic device coupling system of claim 13, wherein said attachment member is attachable to a front surface of an electronic device; and when used in combination with the electronic device, said at least one groove extends along one or more rear outer edges of said outer housing of the electronic device with (i) each of said first groove side surface and said groove end surface extending along said rear surface of said coupling member, (ii) each of said second groove side surface extending along an outer side surface of said outer housing of the electronic device.

16. The electronic device coupling system of claim 13, wherein said attachment member is attachable to a rear surface of an electronic device; and when used in combination with the electronic device, said at least one groove extends along a rear housing surface of said outer housing of the electronic device with each of said first groove side surface, said second groove side surface, and said groove end surface forming inner surfaces of said coupling member.

17. The electronic device coupling system of claim 1, further comprising an electronic device.

18. The electronic device coupling system of claim 17, wherein said electronic device comprises a hand-held device selected from a cellular phone, a smart phone, an electronic computer pad, an electronic game player, a medical monitoring device, a computer, a video player, and an audio player.

19. The electronic device coupling system of claim 1, further comprising a support member, said support member having an overall thickness of less than 0.125 inch.

20. The electronic device coupling system of claim 19, wherein said coupling member, said electronic device, and said support member are attached to one another.
